(19) United States
(12) Patent Application Publication
(10) Pub. No.: US 2024/0083040 A1
(43) Pub. Date: Mar. 14, 2024

(54) SUBSTRATE PROCESSING DEVICE AND METHOD OF CONTROLLING THE SAME

(71) Applicant: Samsung Electronics Co., Ltd., Suwon-si (KR)

(72) Inventors: Jongduk Suh, Suwon-si (KR); Younghak Ko, Suwon-si (KR)

(21) Appl. No.: 18/235,609

(22) Filed: Aug. 18, 2023

(30) Foreign Application Priority Data
Sep. 14, 2022 (KR) 10-2022-0115728
Dec. 6, 2022 (KR) 10-2022-0169097

(51) Int. Cl. B25J 11/00; B65G 47/90

(52) U.S. Cl. CPC B25J 11/0095; B65G 47/905; B65G 2201/0297

(57) ABSTRACT

A method of controlling a substrate processing device includes aligning a door opener with a front side of a door, wherein the door has closed an entrance of a substrate carrier, coupling the door opener to the door, detaching the door from the substrate carrier after the coupling of the door opener to the door, lowering the door opener coupled to the door and exposing the entrance of the substrate carrier, taking out one of a plurality of substrates from the substrate carrier, aligning the door opener coupled to the door to be adjacent to a front side of the entrance of the substrate carrier, the door coupled with the door opener being inclined at an inclination angle with respect to the entrance, lowering the door opener coupled to the door in a second direction perpendicular to the first direction, and taking another substrate out of the substrate carrier.

### CROSS-REFERENCE TO RELATED APPLICATION

This application is based on and claims priority under 35 U.S.C. § 119 to Korean Patent Application No. 10-2022-0115728, filed on Sep. 14, 2022, in the Korean Intellectual Property Office, and Korean Patent Application No. 10-2022-0169097, filed on Dec. 6, 2022, in the Korean Intellectual Property Office, the disclosures of each of which are incorporated by reference herein in their entireties.

### BACKGROUND

The inventive concept relates to a substrate processing device and a method of controlling the same.

During semiconductor manufacturing processes, substrates are processed in a cleanroom to improve the yield of the semiconductor manufacturing processes or the quality of products. However, due to the development or use of more highly integrated devices, finer circuits, and larger substrates, it is difficult to maintain the entire inner space of a cleanroom in a clean state.

Therefore, in recent years, substrate storage devices, such as a front opening unified pod (FOUP) configured to store substrates in an enclosed space, and substrate transfer devices, such as an equipment front end module (EFEM) configured to transfer substrates to a load lock chamber or the like, are used.

### SUMMARY

The inventive concept provides a method of controlling a substrate processing device to prevent a humidity increase for substrates.

The inventive concept is not limited to those mentioned above, and the inventive concept will be apparently understood by those skilled in the art through the following description.

According to an aspect of the inventive concept, a method of controlling a substrate processing device includes aligning a door opener with a front side of a door, wherein the door has closed an entrance of a substrate carrier, and wherein the entrance of the substrate carrier faces in a first direction, coupling the door opener to the door which has closed the entrance of the substrate carrier, detaching the door from the substrate carrier after the coupling of the door opener to the door, lowering the door opener coupled to the door and exposing the entrance of the substrate carrier, taking out one of a plurality of substrates stacked in an internal space of the substrate carrier, aligning the door opener coupled to the door to be adjacent to a front side of the entrance of the substrate carrier, wherein the door coupled with the door opener is inclined at an inclination angle with respect to the entrance of the substrate carrier, lowering the door opener coupled to the door in a second direction perpendicular to the first direction, and taking another substrate out of the substrate carrier.

According to an aspect of the inventive concept, a substrate processing device includes a substrate carrier configured to store a plurality of substrates therein, the substrate carrier comprising an entrance facing in a first direction, a door configured to selectively block the entrance of the substrate carrier and be selectively attached to or detached from the substrate carrier, a transfer robot disposed in front of the entrance of the substrate carrier and configured to take the plurality of substrates out of the substrate carrier, a door opener disposed below the substrate carrier and configured to attach or detach the door to or from the entrance of the substrate carrier, wherein, when the door is detached from the entrance, the door opener is coupled to the door, and the door opener and the door move together as a one unit, and a control unit configured to control, after the transfer robot takes a substrate from the substrate carrier, the door opener coupled to the door to be aligned such that the door opener coupled to the door is adjacent to a front side of the entrance and the door coupled to the door opener is inclined at an inclination angle with respect to the entrance.

According to an aspect of the inventive concept, a substrate processing device includes a substrate carrier configured to stack and store a plurality of substrates therein in a direction perpendicular to a lower surface thereof, the substrate carrier comprising an entrance facing in a first direction, a transfer chamber connected to the substrate carrier through the entrance and comprising a transfer robot therein, the transfer robot being configured to transfer the plurality of substrates from the substrate carrier into an inside of the transfer chamber, a fan filter unit disposed on the transfer chamber and configured to introduce outside air into the transfer chamber, a door configured to selectively block the entrance of the substrate carrier and be selectively attached to or detached from the substrate carrier, a door opener disposed below the substrate carrier and configured to attach or detach the door to or from the entrance of the substrate carrier, wherein, when the door is detached from the entrance, the door opener is coupled to the door, and the door opener and the door move together as a one unit, and a control unit configured to control, after the transfer robot takes a substrate out of the substrate carrier, the door opener such that: the door opener coupled to the door is aligned to be adjacent to a front side of the entrance, the door coupled to the door opener is inclined at an inclination angle with respect to the entrance, the door coupled to the door opener is apart from the entrance by a separation distance increasing in a direction toward an upper portion of the door, and the door opener coupled to the door and the front side of the entrance are apart from each other by a predetermined distance to keep the entrance in an opened state.

### BRIEF DESCRIPTION OF THE DRAWINGS

Embodiments will be more clearly understood from the following detailed description taken in conjunction with the accompanying drawings in which:

FIG. 1 is a plan view illustrating a substrate-processing cluster facility including a substrate transfer device according to an embodiment;

FIG. 2 is a cross-sectional view illustrating the substrate transfer device according to an embodiment;

FIG. 3 is a flowchart illustrating a method of controlling a substrate transfer device according to an embodiment;

FIGS. 4 to 12 are schematic views illustrating a method of controlling a substrate transfer device according to an embodiment;

FIG. 13 is a flowchart illustrating a method of controlling a substrate transfer device according to an embodiment;

FIGS. 14 to 23 are schematic views illustrating a method of controlling a substrate transfer device according to an embodiment; and

FIGS. 24 and 25 are respectively a view and a graph illustrating effects of a substrate transfer device according to an embodiment.

### DETAILED DESCRIPTION OF THE EMBODIMENTS

Hereinafter, embodiments will be described reference to the accompanying drawings. However, the inventive concept is not limited to the embodiments as described below and may be embodied in various other forms. The following embodiments are not provided to fully implement the inventive concept, but are provided to fully convey the scope of the inventive concept to those skilled in the art.

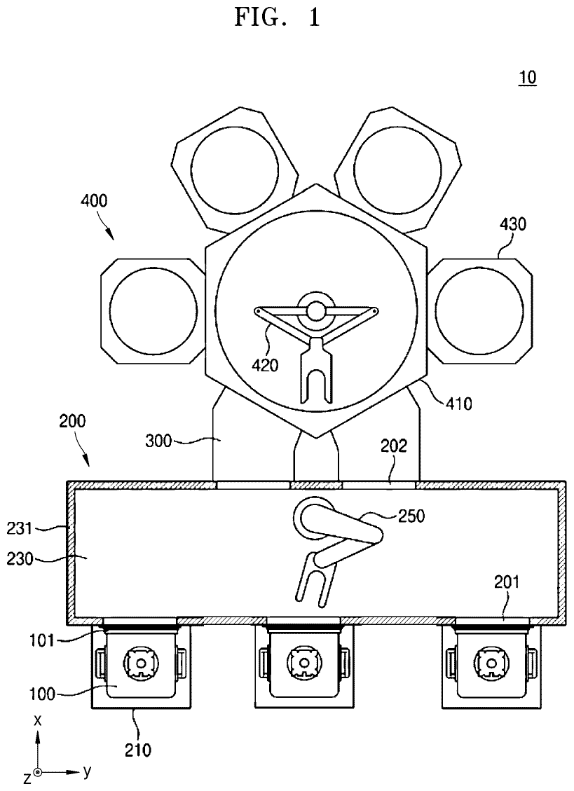

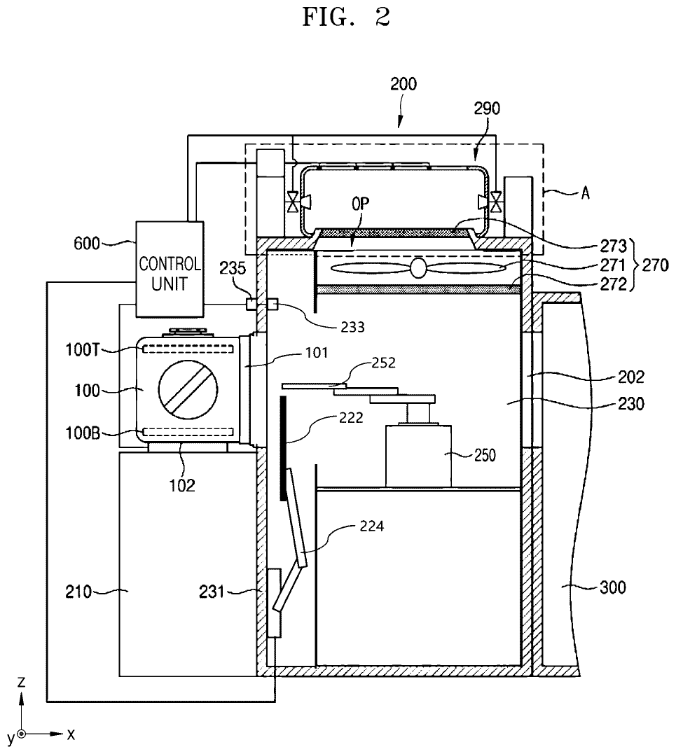

FIG. 1 is a plan view illustrating a substrate-processing cluster apparatus 10 including a substrate transfer device 200 according to an embodiment. FIG. 2 is a cross-sectional view illustrating the substrate transfer device 200 according to an embodiment.

Referring to FIGS. 1 and 2, the substrate-processing cluster apparatus 10 may include a substrate storage device 100, the substrate transfer device 200, a load lock chamber 300, and a substrate treatment device 400.

The substrate storage device 100 (i.e., a substrate carrier with front opening through which a substrate moves in or out) may include a plurality of slots. For example, the substrate storage device 100 may include 25 slots. In the substrate storage device 100, a plurality of substrates may be stacked and stored in a direction perpendicular to a lower surface 102 of the substrate storage device 100 from a lowermost slot 100B to an uppermost slot 100T. The substrate storage device 100 may be connected to the substrate transfer device 200 through a door 101. When no substrate is transferred, the door 101 may close the front opening of the substrate storage device 100 to protect substrates from being contaminated by external substances. A plurality of substrate storage devices 100 may be provided in the substrate storage device 100.

The substrate transfer device 200 may include a load port 210, a first transfer chamber 230, a first transfer robot 250, a fan filter unit 270, a humidity control unit 290, and a control unit 600. The substrate transfer device 200 may transfer substrates from the substrate storage device 100 to the load lock chamber 300.

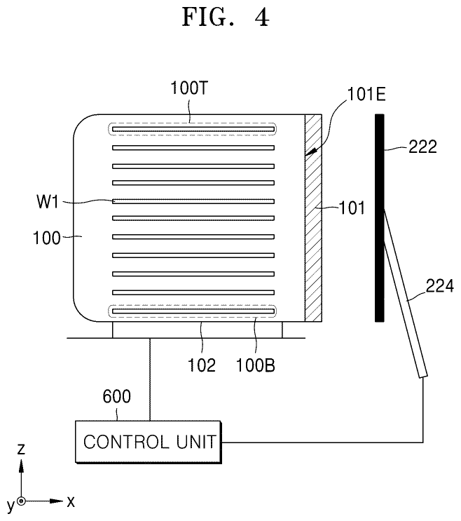

The load port 210 may support the lower surface 102 of the substrate storage device 100 and may be connected to the first transfer chamber 230. The load port 210 may be connected to the control unit 600. The load port 210 may detect, based on contact with the lower surface 102 of the substrate storage device 100, whether the substrate storage device 100 is loaded. For example, when a button provided at an upper surface of the load port 210 is pressed by the lower surface 102 of the substrate storage device 100, the load port 210 may detect that the substrate storage device 100 is loaded. Therefore, the load port 210 may transmit, to the control unit 600, information about whether the substrate storage device 100 is loaded. The load port 210 may include a door opener 222 at a lower lateral side thereof and an arm 224 connected to the door opener 222. The door opener 222 of the load port 210 may be provided below the substrate storage device 100 and may be configured to attach the door 101 to an entrance 101E (refer to FIG. 4) of the substrate storage device 100 or detach the door 101 from the entrance 101E of the substrate storage device 100. This will be further described later with reference to the accompanying drawings. Although not shown in FIGS. 1 and 2, the load port 210 may include a load port gas storage unit. The load port gas storage unit may be connected to the substrate storage device 100 to supply an inert gas to the inside of the substrate storage device 100. The load port 210 and the substrate storage device 100 may be provided in plural in the substrate-processing cluster apparatus 10. A plurality of load ports may be provided to support a plurality of substrate storage devices.

The load port 210 may be connected to a lower portion of a lateral surface of the first transfer chamber 230. At the lateral surface of the first transfer chamber 230 to which the load port 210 is connected, a first door 201 of the substrate transfer device 200 may be connected to the door 101 of the substrate storage device 100. At another lateral surface of the first transfer chamber 230 which is different from the lateral surface of the first transfer chamber 230 to which the load port 210 is connected, the first transfer chamber 230 may be connected to the load lock chamber 300 through a second door 202 of the substrate transfer device 200. A frame 231 of the first transfer chamber 230 may isolate the first transfer chamber 230 from the outside of the first transfer chamber 230. Therefore, a mini-environment may be formed at the inside of the first transfer chamber 230. For example, the first transfer chamber 230 may have an inner space that is defined by the frame 231 and that is separated from the outside of the first transfer chamber 230. The first transfer chamber 230 may include an internal sensor 233 and an external sensor 235. The internal sensor 233 may detect information such as the temperature, the oxygen concentration, and the relative humidity of the inside of the first transfer chamber 230. The external sensor 235 may detect information such as the temperature, the oxygen concentration, and the relative humidity of the outside of the first transfer chamber 230. Each of the internal sensor 233 and the external sensor 235 may be connected to the control unit 600. Therefore, information on the inside and the outside of the first transfer chamber 230 may be transmitted to the control unit 600.

The first transfer robot 250 may be provided at the inside of the first transfer chamber 230. The first transfer robot 250 may transfer a substrate in opposite directions between the substrate storage device 100 and the load lock chamber 300. The first transfer robot 250 may be disposed in front of the entrance 101E (refer to FIG. 4) of the substrate storage device 100 and may take a substrate from the inside of the substrate storage device 100.

The fan filter unit 270 may be provided on the first transfer chamber 230. The humidity control unit 290 may be provided on the fan filter unit 270. The fan filter unit 270 may include a fan 271, a first filter 272, and a second filter 273. The fan filter unit 270 may introduce outside air into the first transfer chamber 230 by operating the fan 271. The pressure of the inside of the first transfer chamber 230 may be maintained higher than the pressure of the outside of the first transfer chamber 230 owing to the operation of the fan 271. Although not shown in FIGS. 1 and 2, the fan 271 may include an impeller to force air to flow into the inside of the first transfer chamber 230, and a casing to guide air into the impeller. The impeller may be a rotating cylinder that has a plurality of blades arranged at even intervals along the circumference of the rotating cylinder. The first filter 272 and the second filter 273 may remove contaminants that may be introduced into the first transfer chamber 230 together with outside air. For example, the first filter 272 may include a high efficiency particulate air (HEPA) filter or an ultra-low penetration air (ULPA) filter. For example, the first filter 272 may be provided below the fan 271. The second filter 273 may include a chemical filter (CF) capable of collecting chemical substances. For example, the second filter 273 may be provided in an opening OP between the fan filter unit 270 and the humidity control unit 290. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. A term that is referenced with a particular ordinal number (e.g., “first” in a particular claim) may be described elsewhere with a different ordinal number (e.g., “second” in the specification or another claim).

The control unit 600 (i.e., a control circuit) may be connected to the load port 210, the internal sensor 233, the external sensor 235, and the humidity control unit 290. The control unit 600 may receive information from the load port 210, the internal sensor 233, and the external sensor 235. The control unit 600 may operate the humidity control unit 290 in two different modes according to the received information. As the control unit 600 controls the humidity control unit 290, outside air and/or inert gas may be selectively introduced into the first transfer chamber 230. The control unit 600 may be connected to the door opener 222 to control the operation of the door opener 222. This will be further described later with reference to the accompanying drawings. Although not illustrated, the control unit 600 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the processing controller 1020 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

The load lock chamber 300 may connect the substrate transfer device 200 and the substrate treatment device 400 to each other. The substrate transfer device 200 and the load lock chamber 300 may be connected with each other through the second door 202 of the substrate transfer device 200. The load lock chamber 300 may temporarily accommodate a transferred substrate. When no substrate is transferred, the second door 202 of the substrate transfer device 200 may be closed to maintain the load lock chamber 300 in a vacuum.

The substrate treatment device 400 may include a second transfer chamber 410, a second transfer robot 420, and a plurality of process chambers 430. The second transfer chamber 410 may be connected to the load lock chamber 300 and the process chambers 430. The second transfer robot 420 may be provided at the inside of the second transfer chamber 410. The second transfer robot 420 may transfer substrates between the load lock chamber 300 and the process chambers 430 or between the process chambers 430. Various semiconductor manufacturing processes may be performed in each of the process chambers 430. Although not shown in FIGS. 1 and 2, the load lock chamber 300 and the substrate treatment device 400 may be connected to a vacuum creation unit (e.g., a vacuum pump) such that the load lock chamber 300 and the substrate treatment device 400 may be maintained in a vacuum state.

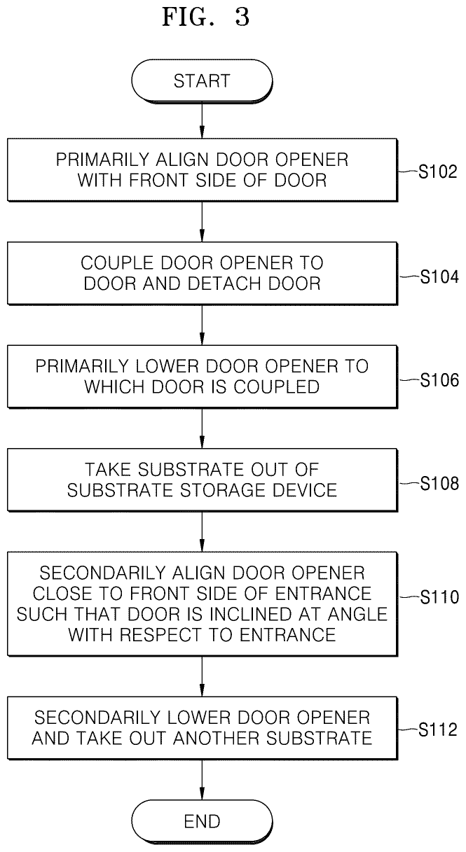

FIG. 3 is a flowchart illustrating a method of controlling a substrate transfer device according to an embodiment. FIGS. 4 to 12 are schematic views illustrating a method of controlling a substrate transfer device according to an embodiment. For example, FIG. 3 illustrates a method of controlling the substrate transfer device 200 to prevent a humidity increase for substrates accommodated in the substrate storage device 100 during a time when substrates are taken out of the substrate storage device 100.

Referring to FIGS. 3 and 4, in operation S102, the door opener 222 may be primarily aligned with a front side of the door 101. When the substrate storage device 100 is loaded on the load port 210, the entrance 101E of the substrate storage device 100 may be open in a first direction (x-axis direction), and the door 101 may be arranged to selectively block the entrance 101E of the substrate storage device 100. The door 101 may be selectively attached to or detached from the substrate storage device 100 as described later.

The control unit 600 may control the operation of the door opener 222 through the arm 224. The control unit 600 may align the door opener 222 with the front side of the door 101, and in this case, the door opener 222 may be aligned such that an upper surface of the door opener 222 and an upper surface of the door 101 may be parallel with each other. Although the upper surface of the door opener 222 and the upper surface of the door 101 are illustrated as having substantially the same area, the upper surface of the door opener 222 and the upper surface of the door 101 may have different areas depending on embodiments.

As shown in FIG. 4, a plurality of substrates may be stacked and accommodated in the substrate storage device 100 from the lowermost slot 100B to the uppermost slot 100T in a direction perpendicular to the lower surface 102 of the substrate storage device 100. The substrate storage device 100 may store a plurality of substrates therein.

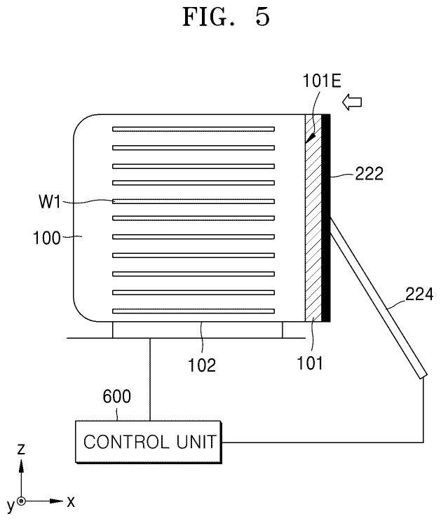

Referring to FIGS. 3, 5, and 6, after operation S102, in operation S104, the door opener 222 may be coupled to the door 101, and then the door 101 may be detached from the substrate storage device 100. First, as shown in FIG. 5, the control unit 600 may control driving of the arm 224 to couple the door opener 222 to the door 101. In this case, the door opener 222 may be physically coupled to a fastener (not shown) formed on the door 101. However, embodiments are not limited thereto. For example, the door opener 222 may include an electrostatic chuck and may be coupled to the door 101 by a magnetic force. After the door 101 is detached from the entrance 101E, the door opener 222 and the door 101 may be moved together in a coupled state as a one unit. In some embodiments, the door 101 may include or may be formed of a sheet of plate including metal. The door 101 may be coupled with the door opener 222 using a magnetic force generated therefrom.

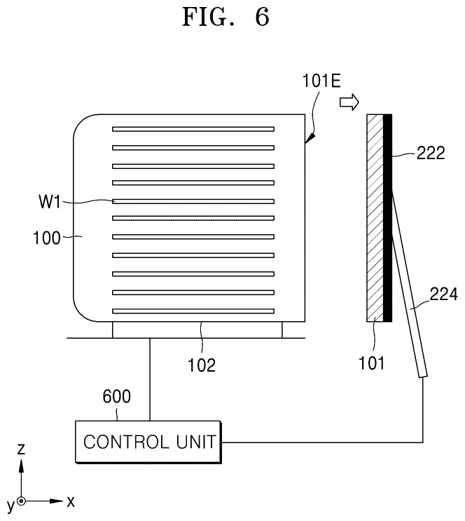

Thereafter, as shown in FIG. 6, the door 101 may be detached from the substrate storage device 100. The control unit 600 may control the arm 224 to move the door opener 222 coupled to the door 101 in the first direction (x-axis direction). As the door 101 is detached from the substrate storage device 100, the entrance 101E of the substrate storage device 100 may be exposed. In some embodiments, the substrate storage device 100 may be coupled with the door 101 using a magnetic force generated therefrom. In this case, the magnetic force between the door opened 222 and the door 101 is stronger than the magnetic force between the door 101 and the substrate storage device 100. The coupling method between the substrate storage device 100 and the door 101 is not limited to the above. In another embodiments, the substrate storage device 100 may be coupled with the door 101 using a screw joint.

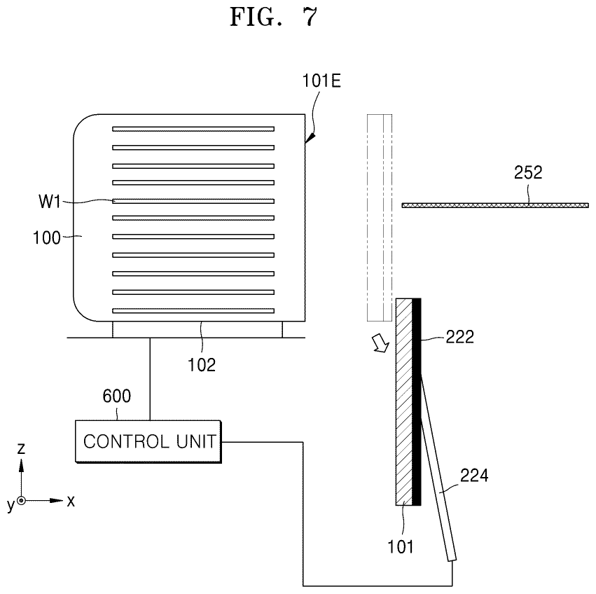

Referring to FIGS. 3 and 7, in operation S106, the door opener 222 to which the door 101 is coupled may be primarily lowered to completely expose the entrance 101E of the substrate storage device 100 in the first direction (x-axis direction). For example, the control unit 600 may lower the door opener 222 to which the door 101 is coupled. In this case, the door opener 222 may be lowered in a second direction (negative z-axis direction) perpendicular to the first direction (x-axis direction). However, embodiments are not limited thereto, and for example, the door opener 222 may be obliquely lowered. The control unit 600 may align a transfer arm 252 of the first transfer robot 250 (refer to FIG. 1) with a front side of the entrance 101E of the substrate storage device 100. In some embodiments, the controller unit 600 may lower the door opener 222 that has been coupled to the door 101 to expose the front side of the entrance 101E, thereby allowing the transfer arm 252 to approach one of the plurality of substrates in the substrate storage device 100 through the entrance 101E.

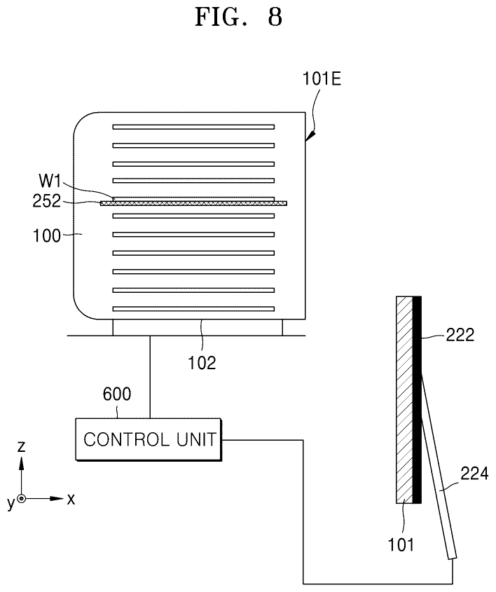

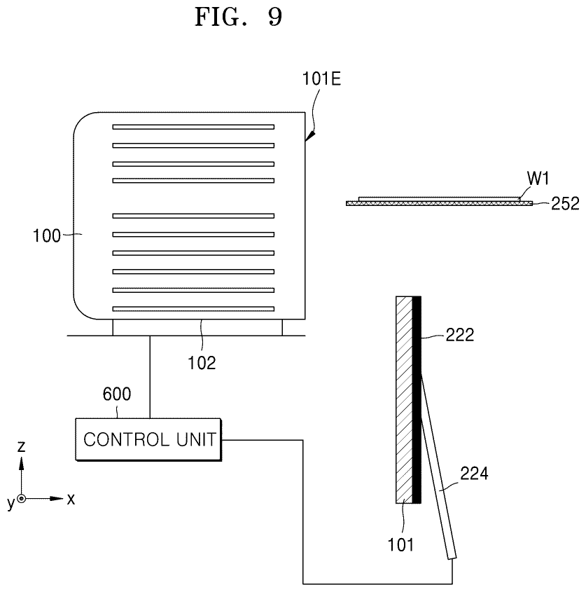

Then, referring to FIGS. 3, 8, and 9, in operation S108, a first substrate W1 among a plurality of substrates stacked in an internal space of the substrate storage device 100 may be taken out. The transfer arm 252 of the first transfer robot 250 may be moved into the substrate storage device 100 through the entrance 101E of the substrate storage device 100 to take out the first substrate W1. In FIGS. 8 and 9, the first substrate W1 is the seventh substrate from the bottom of the substrate storage device 100. However, embodiments are not limited thereto, and for example, the first substrate W1 may be the uppermost substrate.

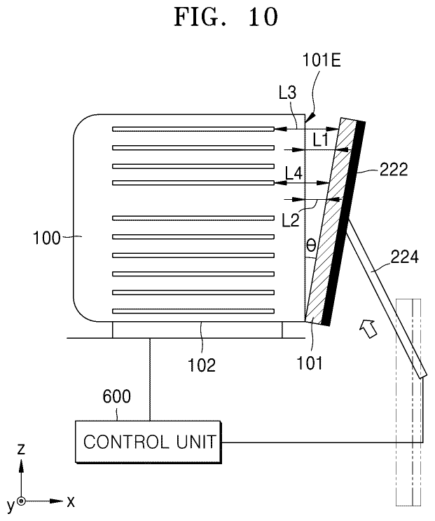

Referring to FIGS. 3 and 10, in operation S110, the control unit 600 drives the arm 224 such that the door opener 222 may be secondarily aligned to be adjacent to the front side of the entrance 101E in a state in which the door 101 coupled with the door opener 222 is inclined at an angle θ (i.e., an inclination angle) with respect to the entrance 101E. The inclination angle may be selected from a range of about 10 degrees to 45 degrees. If the inclination angle is more than 45 degrees, external moisture may penetrate into the substrate storage device. The inclination angle can be defined as an angle between a direction parallel to the upper surface of the door 101 (e.g., the z direction) and a direction orthogonal to the upper surface of the door 101 (e.g., the x direction) when combined with door 101 and substrate storage device 100.

In operation S110, the door opener 222 may be aligned such that the door 101 coupled to the door opener 222 may be at a varying distance from the entrance 101E in the first direction (x-axis direction). As shown in FIG. 10, an upper end of the entrance 101E and an upper end of the door 101 may be apart from each other by a first separation distance L1. A middle portion of the entrance 101E and a middle portion of the door 101 may be apart from each other by a second separation distance L2. The first separation distance L1 is greater than the second separation distance L2. Therefore, the separation distance between the entrance 101E and the door 101 increases in a direction toward the upper end of the door 101. A lower portion of the entrance 101E and a lower portion of the door 101 may contact each other or may be spaced apart from each other at a distance smaller than the second separation distance L2.

According to an embodiment, in operation S110, the door opener 222 may be aligned such that the distance between the door 101 coupled to the door opener 222 and the substrates accommodated at the inside of the substrate storage device 100 may increase in an upward direction. For example, as shown in FIG. 10, the separation distance between the door 101 and the uppermost substrate in the substrate storage device 100 may be referred to as a third separation distance L3. The separation distance between the door 101 and the fourth substrate from the top at the inside of the substrate storage device 100 may be referred as a fourth separation distance L4. The third separation distance L3 is greater than the fourth separation distance L4. The distance between the door 101 coupled to the door opener 222 and the substrates accommodated in the substrate storage device 100 increases in the upward direction.

According to an embodiment, in operation S110, the door opener 222 may be aligned such that the door 101 may be apart from the front side of the entrance 101E of the substrate storage device 100 by a predetermined distance to maintain the entrance 101E of the substrate storage device 100 in an opened state. Therefore, when the door opener 222 is aligned to be adjacent to the front side of the entrance 101E, the entrance 101E may not be blocked. Because the door opener 222 is aligned to be adjacent to the front side of the entrance 101E without blocking the entrance 101E, the amount of outside air flowing into the substrate storage device 100 may be reduced. An increase in the humidity of the inside of the substrate storage device 100 may be prevented by reducing the amount of outside air flowing into the substrate storage device 100. In addition, because the door 101 is not coupled to the substrate storage device 100 again, the door 101 may not be repeatedly attached and detached each time a substrate is taken out of the substrate storage device 100, and thus the door 101 may be less damaged.

The angle θ may be selected from a range of about 10 degrees to about 45 degrees. Referring to FIG. 2, when the fan 271 of the fan filter unit 270 is rotated at a high speed, a strong air current may be generated at the inside of the first transfer chamber 230. When the entrance 101E of the substrate storage device 100 is opened, the substrates accommodated at the inside of the substrate storage device 100 may be exposed to the air current that is generated by the fan 271, and particularly, substrates accommodated in a lower portion of the substrate storage device 100 may be more likely to be exposed to the air current. The substrates accommodated in the lower portion of the substrate storage device 100 may be protected from the air current by aligning the door opener 222 to be adjacent to the front side of the entrance 101E with the door 101 being inclined at the angle θ with respect to the entrance 101E. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

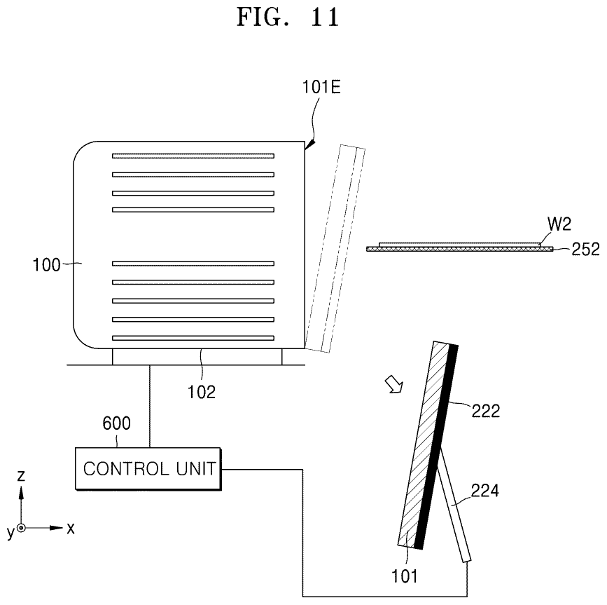

Then, referring to FIGS. 3 and 11, in operation S112, the door opener 222 may be secondarily lowered, and a second substrate W2 may be taken out of the substrate storage device 100. The control unit 600 may drive the arm 224 to secondarily lower the door opener 222. The door opener 222 may be lowered in the second direction (negative z-axis direction) perpendicular to the first direction (x-axis direction). However, embodiments are not limited thereto, and the door opener 222 may be obliquely lowered. The control unit 600 may control the door opener 222 such that the door opener 222 may be secondarily lowered in a state in which the door opener 222 is inclined at the angle θ. Therefore, there is no need to control the upper surface of the door opener 222 to be parallel with an end surface of the entrance 101E of the substrate storage device 100, and thus the operation of the door opener 222 may be efficiently controlled.

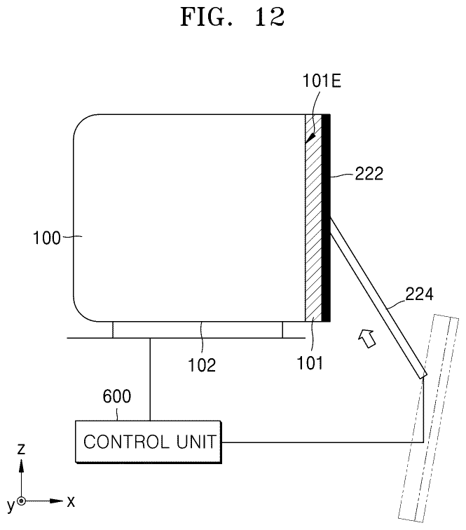

After the door opener 222 is lowered in the second direction (negative z-axis direction), another substrate may be taken out from the inside of the substrate storage device 100. Thereafter, all the substrates remaining in the substrate storage device 100 may be taken out by repeating the operation of lowering the door opener 222, the operation of taking out a substrate, and the operation of aligning the door opener 222 without completely closing the entrance 101E of the substrate storage device 100 with the door 101. Referring to FIG. 12, after all the substrates stacked in the internal space of the substrate storage device 100 are taken out, the door 101 may be coupled to the substrate storage device 100 to completely close the entrance 101E of the substrate storage device 100. In an embodiment, the inclination angle may remain unchanged during a time when each substrate is taken out of the substrate storage device 100. The present invention, however, is not limited thereto. In an embodiment, the inclination angle may be adjusted during a time when each substrate is taken out of the substrate storage device 100. As the air flow velocity or humidity increases, the inclination angle may decrease.

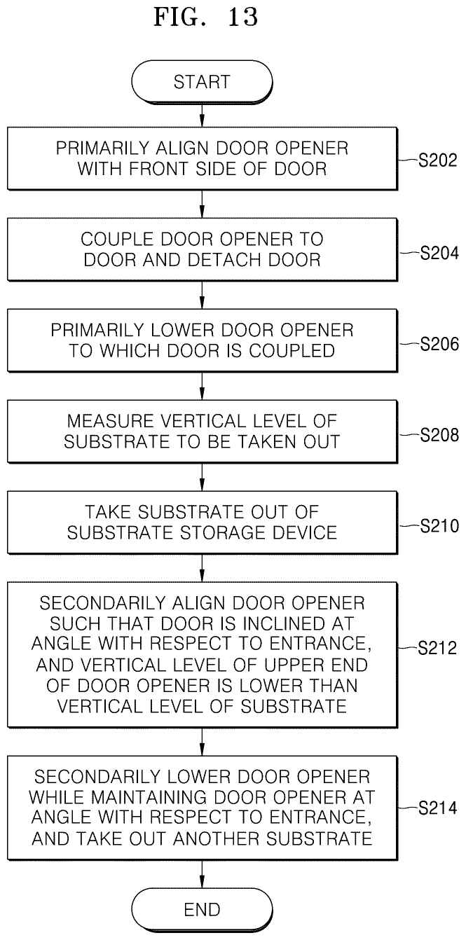

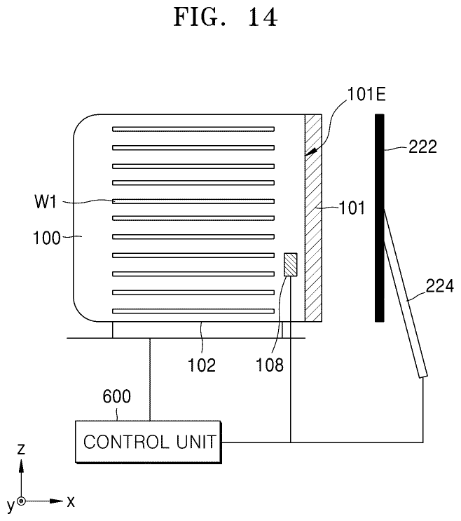

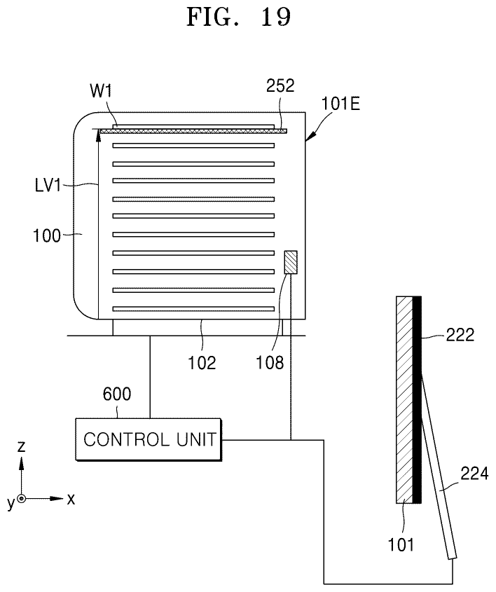

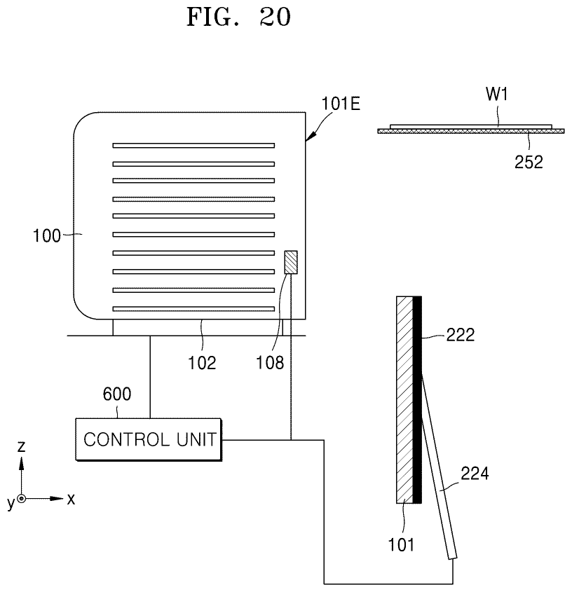

FIG. 13 is a flowchart illustrating a method of controlling a substrate transfer device according to an embodiment. FIGS. 14 to 23 are schematic views illustrating a method of controlling a substrate transfer device according to an embodiment. For example, FIG. 13 illustrates a method of controlling the substrate transfer device 200 to prevent a humidity increase for substrates accommodated in the substrate storage device 100 during a time when substrates are taken out of the substrate storage device 100. In the following description of the method of controlling the substrate transfer device 200, those described with reference to FIG. 3 may be simply described or may be omitted.

Referring to FIGS. 13 and 14, the substrate transfer device 200 may include the substrate storage device 100 having the entrance 101E facing in a first direction (x-axis direction). In operation S202, the door opener 222 may be primarily aligned with the front side of the door 101 that blocks the entrance 101E of the substrate storage device 100 facing in the first direction (x-axis direction). A position sensor 108 may be located at the inside of the substrate storage device 100, and may be connected to the control unit 600.

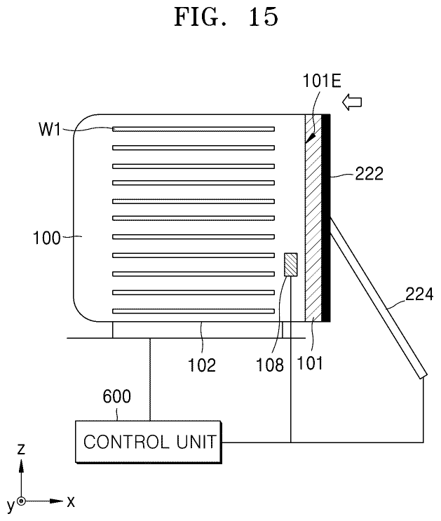

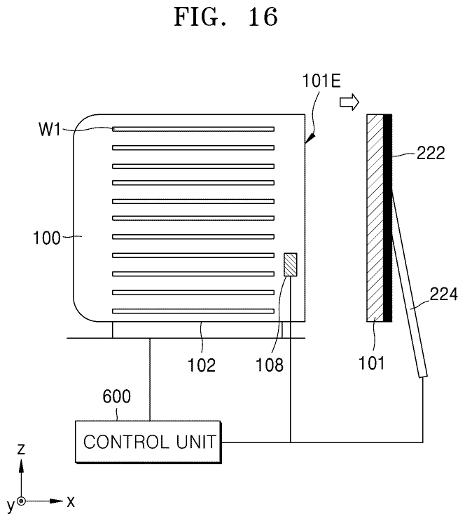

Referring to FIGS. 13, 15, and 16, in operation S204 after operation S202, the door opener 222 may be coupled to the door 101, and then the door 101 may be separated from the substrate storage device 100. As shown in FIGS. 15 and 16, the control unit 600 may control driving of the arm 224 such that the door opener 222 and the door 101 are coupled to each other.

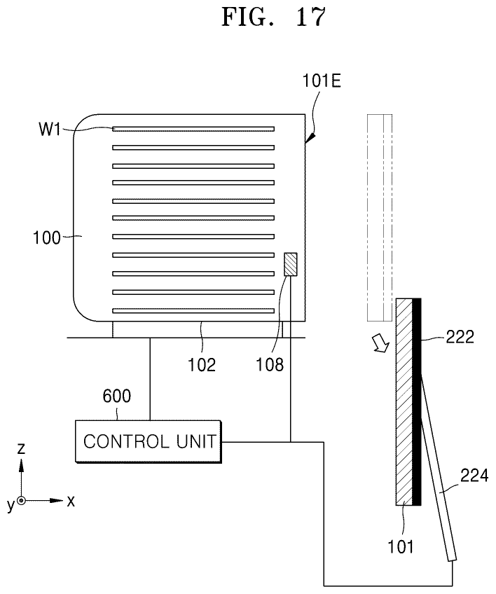

Referring to FIGS. 13 and 17, in operation S206, the door opener 222 coupled to the door 101 may be primarily lowered such that the entrance 101E of the substrate storage device 100 may be exposed.

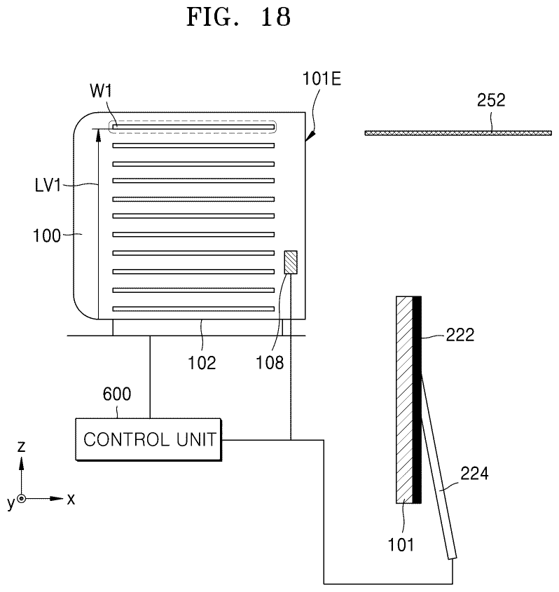

Referring to FIGS. 13 and 18, the position sensor 108 may measure vertical levels of a plurality of substrates stored at the inside of the substrate storage device 100. In operation S208, the position sensor 108 may measure the vertical level of a first substrate W1 to be taken out of the substrate storage device 100. For example, the position sensor 108 according to an embodiment, the position sensor 108 may be a distance measurement sensor. The distance measurement sensor measures the distance to the measurement object by transmitting signals such as light, sound, and radio waves and measuring the return time. For example, position sensor 108 may include a ToF (Time of Flight) sensor, a LiDAR (Light Detection And Ranging) sensor, etc. However, it is not limited to the examples listed above.

Referring to FIGS. 13, 19, and 20, in operation S210, among the plurality of substrates stacked in the inside of the substrate storage device 100, the first substrate W1 to be taken out. For example, the transfer arm 252 of the first transfer robot 250 (refer to FIG. 1) may take the first substrate W1 out of the substrate storage device 100 through the entrance 101E of the substrate storage device 100 from which the door 101 is detached.

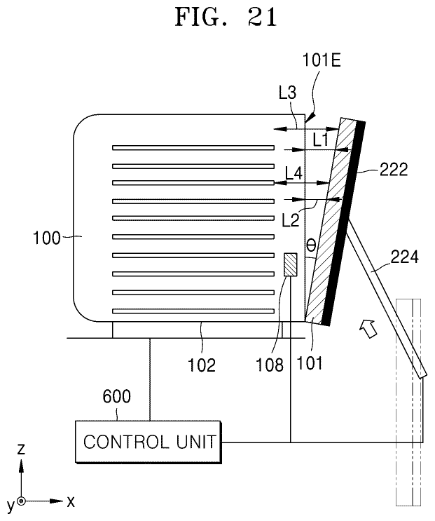

Referring to FIGS. 13 and 21, in operation S212, the control unit 600 drives the arm 224 to secondarily align the door opener 222 to be adjacent to the front side of the entrance 101E of the substrate storage device 100 such that the door 101 coupled to the door opener 222 may be inclined at an angle θ with respect to the entrance 101E of the substrate storage device 100.

In operation S212, the door opener 222 may be aligned such that the vertical level LV2 of an uppermost end of the door opener 222 may be lower than the vertical level LV1 of the first substrate W1 measured before the first substrate W1 is taken out of the substrate storage device 100. Air may flow into the substrate storage device 100 through a lower portion of the substrate storage device 100, and thus the effect of maintaining humidity for the substrates accommodated in the substrate storage device 100 may be obtained thus even when the door opener 222 is aligned such that the vertical level LV2 of the uppermost end of the door opener 222 is lower than the vertical level LV1 of the first substrate W1 that has already been taken out. Because the door opener 222 is aligned such that the vertical level LV2 of the uppermost end of the door opener 222 is lower than the vertical level LV1 of the first substrate W1 that has already been taken out, the range in which the door opener 222 moves may be reduced.

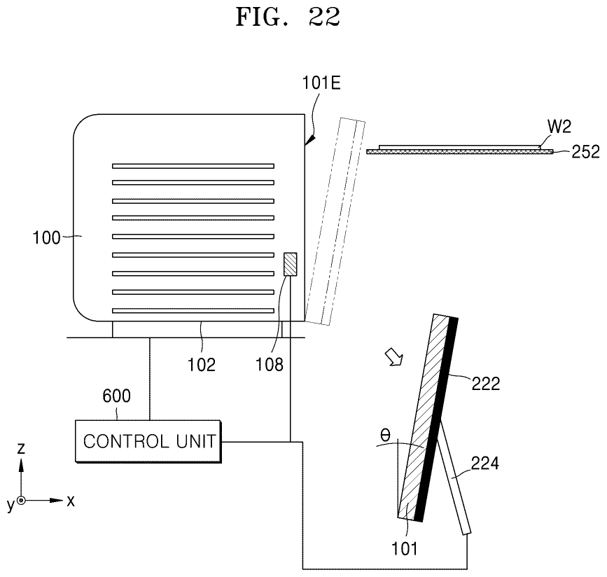

Referring to FIGS. 13 and 22, in operation S214, the door opener 222 may be secondarily lowered, and another second substrate W2 may be taken out of the substrate storage device 100. The control unit 600 may drive the arm 224 to secondarily lower the door opener 222. The door opener 222 may be lowered in a second direction (negative z-axis direction) perpendicular to the first direction (x-axis direction). However, embodiments are not limited thereto, and for example, the door opener 222 may be obliquely lowered. The control unit 600 may control the door opener 222 such that the door opener 222 may be lowered in a state in which the door opener 222 is inclined at the angle θ. Therefore, there is no need to control the upper surface of the door opener 222 to be parallel to an end surface of the entrance 101E of the substrate storage device 100, and thus the operation of the door opener 222 may be efficiently controlled.

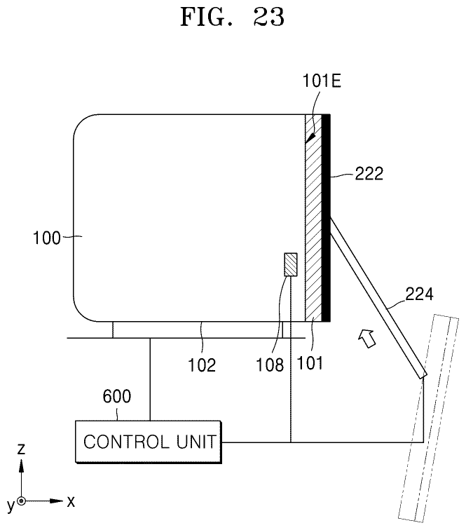

Thereafter, all the substrates remaining in the substrate storage device 100 may be taken out by repeating the operation of lowering the door opener 222, the operation of taking out a substrate, and the operation of aligning the door opener 222 without completely closing the entrance 101E of the substrate storage device 100 with the door 101. Referring to FIG. 23, after all the substrates stacked in the internal space of the substrate storage device 100 are taken out, the door 101 may be coupled to the substrate storage device 100 to completely close the entrance 101E of the substrate storage device 100.

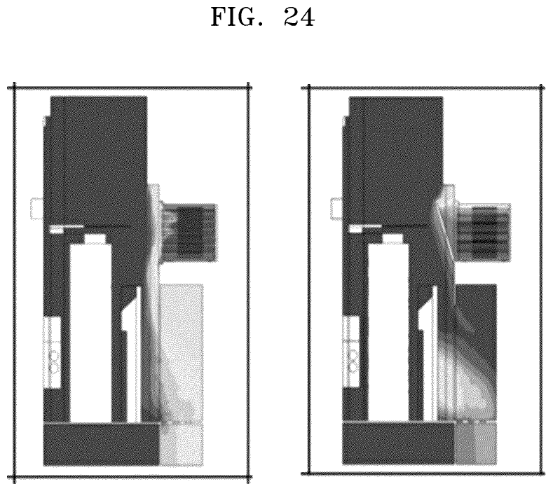

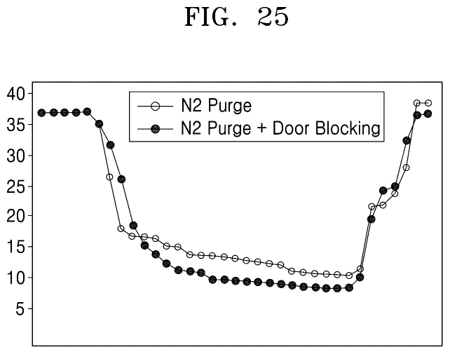

FIGS. 24 and 25 are respectively a view and a graph illustrating effects of a substrate transfer device according to an embodiment.

For example, an image on the left side of FIG. 24 shows results of a simulation in which the flow of air is observed by opening an entrance of the substrate storage device, and an image on the right side of FIG. 24 shows results of a simulation in which the flow of air is observed by aligning and maintaining a door close to the entrance of the substrate storage device at an angle with respect to the entrance of the substrate storage device.

Referring to the left image, when the entrance of the substrate storage device is opened, a large amount of air containing moisture flows into the substrate storage device. Referring to the right image, when the door is aligned to be adjacent to the entrance of the substrate storage device, a relatively small amount of air flows into the substrate storage device.

Referring to FIG. 25, the vertical axis refers to relative humidity at the inside of the substrate storage device 100, and the horizontal axis refers to time. A curve connecting white dots refers to the case in which the door is not aligned to be adjacent to the entrance of the substrate storage device, and a curve connecting black dots refers to the case in which the door is aligned to be adjacent to the entrance of the substrate storage device at an angle with respect to the entrance of the substrate storage device. As shown in FIG. 25, when the door is aligned to be adjacent to the entrance of the substrate storage device at an angle with respect to the entrance of the substrate storage device, the humidity at the inside of the substrate storage device could be maintained at a relatively low level.

While the inventive concept has been particularly shown and described with reference to embodiments thereof, it will be understood that various changes in form and details may be made therein without departing from the spirit and scope of the following claims.

What is claimed is:

1. A method of controlling a substrate processing device, the method comprising:
aligning a door opener with a front side of a door, wherein the door has closed an entrance of a substrate carrier, and wherein the entrance of the substrate carrier faces in a first direction;
coupling the door opener to the door which has closed the entrance of the substrate carrier;
detaching the door from the substrate carrier after the coupling of the door opener to the door;
lowering the door opener coupled to the door and exposing the entrance of the substrate carrier;
taking out one of a plurality of substrates stacked in an internal space of the substrate carrier;
aligning the door opener coupled to the door to be adjacent to a front side of the entrance of the substrate carrier, wherein the door coupled with the door opener is inclined at an inclination angle with respect to the entrance of the substrate carrier;
lowering the door opener coupled to the door in a second direction perpendicular to the first direction; and
taking another substrate out of the substrate carrier.

2. The method of claim 1,
wherein the inclination angle between the door and the entrance of the substrate carrier is selected from a range of about 10 degrees to about 45 degrees.

3. The method of claim 1,
wherein, in the aligning of the door opener coupled to the door to be adjacent to the front side of the entrance of the substrate carrier, the door coupled with the door opener are apart from the front side of the entrance of the substrate in the first direction by a separation distance, and
wherein the separation distance between the entrance of the substrate carrier and the door increases in a direction toward an upper portion of the door.

4. The method of claim 1,
wherein, in the aligning of the door opener with the front side of the door, an upper surface of the door opener and an upper surface of the door are parallel with each other.

5. The method of claim 1,
wherein, in the aligning of the door opener coupled to the door to be adjacent to the front side of the entrance of the substrate carrier, a distance in the first direction between the door coupled with the door opener and the plurality of substrates stacked inside the substrate carrier increases in an upward direction that is perpendicular to the first direction.

6. The method of claim 1,
wherein, in the aligning of the door opener coupled to the door to be adjacent to the front side of the entrance of the substrate carrier, the door and the front side of the entrance of the substrate carrier are apart from each other by a predetermined distance to maintain the entrance of the substrate carrier in an opened state.

7. The method of claim 1, further comprising:
after the lowering of the door opener in the second direction and after all of the plurality of substrates are taken out of the substrate carrier, completely closing the entrance of the substrate carrier by coupling the door to the entrance of the substrate carrier.

8. The method of claim 1, further comprising:
measuring a vertical level of a substrate to be taken out of the substrate carrier.

9. The method of claim 8,
wherein, in the aligning of the door opener coupled to the door to be adjacent to the front side of the entrance of the substrate carrier, a vertical level of an uppermost end of the door opener is lower than the measured vertical level of the substrate.

10. The method of claim 8,
wherein, in the lowering of the door opener coupled to the door in the second direction and the taking of another substrate out of the substrate carrier, the inclination angle of the door opener is maintained.

11. A substrate processing device comprising:
a substrate carrier configured to store a plurality of substrates therein, the substrate carrier comprising an entrance facing in a first direction;
a door configured to selectively block the entrance of the substrate carrier and be selectively attached to or detached from the substrate carrier;
a transfer robot disposed in front of the entrance of the substrate carrier and configured to take the plurality of substrates out of the substrate carrier;
a door opener disposed below the substrate carrier and configured to attach or detach the door to or from the entrance of the substrate carrier, wherein, when the door is detached from the entrance, the door opener is coupled to the door, and the door opener and the door move together as a one unit; and
a control unit configured to control, after the transfer robot takes a substrate from the substrate carrier, the door opener coupled to the door to be aligned such that the door opener coupled to the door is adjacent to a front side of the entrance and the door coupled to the door opener is inclined at an inclination angle with respect to the entrance.

12. The substrate processing device of claim 11,
wherein the inclination angle is selected from a range of about 10 degrees to about 45 degrees.

13. The substrate processing device of claim 11,
wherein the control unit controls the door opener such that the door coupled to the door opener is aligned to be adjacent to the front side of the entrance and is apart from the entrance by a separation distance, and
wherein the separation distance increases in a direction toward an upper portion of the door.

14. The substrate processing device of claim 11,
wherein the substrate carrier comprises a plurality of substrates stacked therein in a second direction perpendicular to the first direction, and
wherein the control unit controls the door opener such that when the door opener coupled to the door is aligned to be adjacent to the front side of the entrance, a distance between the door opener that is aligned to be adjacent to the front side of the entrance and the plurality of substrates increases in an upward direction that is perpendicular to the first direction.

15. The substrate processing device of claim 11,
wherein the control unit controls the door opener such that when the door opener coupled to the door is aligned to be adjacent to the front side of the entrance, the door opener and the front side of the entrance are apart from each other by a predetermined distance to maintain the entrance in an opened state.

16. The substrate processing device of claim 11,
wherein the substrate carrier comprises a position sensor configured to measure a vertical level of a substrate, among the plurality of substrates stored inside the substrate carrier, to be taken out of the substrate carrier.

17. The substrate processing device of claim 16,
wherein the control unit controls the door opener such that when the door opener coupled to the door is aligned to be adjacent to the front side of the entrance, a vertical level of an uppermost end of the door that is coupled to the door opener is lower than the measured vertical level of the substrate to be taken out of the substrate carrier among the plurality of substrates.

18. The substrate processing device of claim 11,
wherein the control unit controls, after aligning the door opener coupled to the door to be adjacent to the front side of the entrance, the door opener to be lowered while maintaining the inclination angle.

19. A substrate processing device comprising:
a substrate carrier configured to stack and store a plurality of substrates therein in a direction perpendicular to a lower surface thereof, the substrate carrier comprising an entrance facing in a first direction;
a transfer chamber connected to the substrate carrier through the entrance and comprising a transfer robot therein, the transfer robot being configured to transfer the plurality of substrates from the substrate carrier into an inside of the transfer chamber;
a fan filter unit disposed on the transfer chamber and configured to introduce outside air into the transfer chamber;
a door configured to selectively block the entrance of the substrate carrier and be selectively attached to or detached from the substrate carrier;
a door opener disposed below the substrate carrier and configured to attach or detach the door to or from the entrance of the substrate carrier, wherein, when the door is detached from the entrance, the door opener is coupled to the door, and the door opener and the door move together as a one unit; and
a control unit configured to control, after the transfer robot takes a substrate out of the substrate carrier, the door opener such that:
the door opener coupled to the door is aligned to be adjacent to a front side of the entrance,
the door coupled to the door opener is inclined at an inclination angle with respect to the entrance,
the door coupled to the door opener is apart from the entrance by a separation distance increasing in a direction toward an upper portion of the door, and
the door opener coupled to the door and the front side of the entrance are apart from each other by a predetermined distance to keep the entrance in an opened state.

20. The substrate processing device of claim 19,
wherein the substrate carrier comprises a position sensor configured to measure a vertical level of a substrate, to be taken out of the substrate carrier, among the plurality of substrates stored inside the substrate carrier, and
wherein the control unit is configured to align the door opener such that a vertical level of an uppermost end of the door coupled with the door opener is lower than the measured vertical level of the substrate to be taken out of the substrate carrier among the plurality of substrates.
